(19) United States
(12) Patent Application Publication
(10) Pub. No.: US 2004/0246001 A1
(43) Pub. Date: Dec. 9, 2004

(54) Method and apparatus for guided establishment of a signal probe configuration

(76) Inventors: David N. Sontag, Colorado Springs, CO (US); James H. Holland, Monument, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/457,172

(22) Filed: Jun. 9, 2003

(51) Int. Cl. H01H 31/02; G01R 31/308

(52) U.S. Cl. 324/537; 324/753

(57) ABSTRACT

A method and apparatus for establishing a probe configuration comprises displaying a signal icon, a measurement channel icon, and a probe configuration partition interposed therebetween. The probe configuration partition reflects the electrical characteristics of a circuit interposed between a probed signal and a measurement channel of an oscilloscope. The method accepts changes to the probe configuration partition to generate the probe configuration and uses the probe configuration to adapt a probed signal for presentation to a user.

### BACKGROUND

There are a large number of different oscilloscope probes. Examples of different probes include active and passive oscilloscope probes, probes with gain, probes with attenuation, and probes with impedance matching circuits. Because a probe is placed between a signal being measured and a measurement circuit in the oscilloscope, electrical characteristics of a probe affect that which is presented to the measurement circuit. Accordingly, a probed signal may be different from a measured signal. This is especially true as users require probing higher and higher frequency signals. Without some intelligence in the oscilloscope, the oscilloscope displays the signal presented at the measurement channel and not the signal being probed. It is desirable, however, for the oscilloscope to display the probed signal so that a user may infer circuit performance based upon it. If a digital oscilloscope has knowledge of a probe configuration, it is possible for the oscilloscope to display the probed signal using computational operations on the measured signal according to the probe configuration. Accordingly, it is beneficial if an oscilloscope user is able to accurately and completely provide the probe configuration information to the oscilloscope.

Conventional probe configuration methods include one or more dialog boxes to present a collection of all available options for various probe settings. All of these settings affect how an acquired signal is represented on an oscilloscope display. Because of this, accurate settings are important in helping a user make accurate inferences from the displayed signal. One disadvantage with conventional probe configuration methods is that the user interfaces are not intuitive because all options are presented and it is incumbent upon the user to decipher the interface and select the appropriate options for the probe that is attached to the oscilloscope. This is particularly difficult when both basic and advanced settings are presented at the same level. Most users will use only the basic settings, but must sift through and know to not select the advanced settings for most accurate probe configuration. Another disadvantage is that internal and external probe settings are contained within the same dialog box. In many cases, it is unclear to a user exactly what a particular setting means in terms of how it affects the probed signal and the presentation of the probed signal.

There is a need, therefore, for a more intuitive user interface for oscilloscope probe configuration.

### SUMMARY

A method of establishing a probe configuration comprises displaying a signal icon and a measurement channel icon, displaying a probe configuration partition interposed between the input icon and the measurement icon that reflects the electrical characteristics of a circuit interposed between a probed signal and a measurement channel. The method accepts changes to the probe configuration partition to generate the probe configuration, and uses the probe configuration to adapt a probed signal for presentation to a user.

According to another aspect of the present teachings, an apparatus for establishing a probe configuration and measuring an electrical signal comprises a display showing a signal icon, a measurement icon, and a probe configuration partition disposed between the input icon and the measurement icon that reflects the electrical characteristics of a probe. The apparatus further comprises means for accepting changes to the probe configuration partition to generate the probe configuration, means for measuring the signal with the probe to obtain a measured signal, and means for adapting the measured signal according to the probe configuration for presentation of the signal to a user.

### BRIEF DESCRIPTION OF THE DRAWINGS

FIG. 1 shows a perspective view of a conventional probing solution of a printed circuit board for measurement of a signal on an oscilloscope.

FIGS. 2-9 illustrate various embodiments of probe configuration menus and partitions according to the present teachings.

FIG. 10 is a flow chart of a method for using a probe according to the present teachings.

FIG. 11 is a flow chart of a method for administering a probe configuration according to the present teachings.

### DETAILED DESCRIPTION

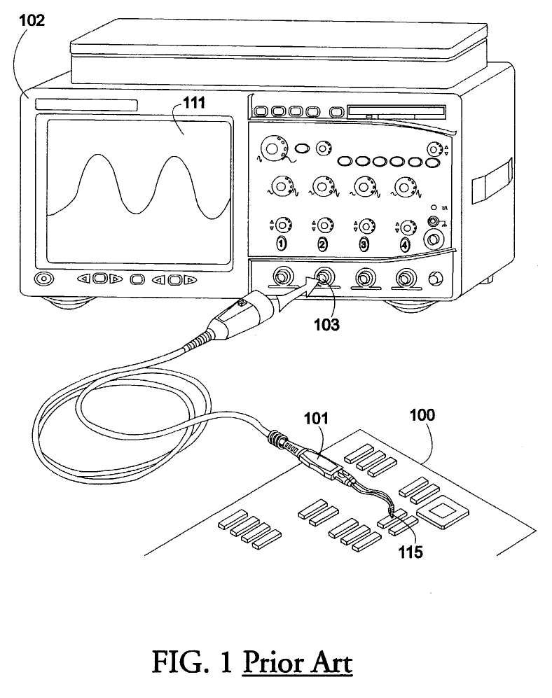

With specific reference to FIG. 1 of the drawings, there is shown a perspective view of an electrical signal on a printed circuit board 100 being sampled by a probe 101 and measured by an oscilloscope 102. For consistency of nomenclature, an electrical signal on the PCB 100 is referred to as a “probed signal” and a signal presented to an oscilloscope measurement channel 103 is a “measured signal”. As one of ordinary skill in the art appreciates, the probe 101 comprises an electrical circuit interposed between the probed signal and the measured signal. Ideally, the measured signal is an accurate representation of the probed signal. Depending upon the frequency of the probed signal, the electrical characteristics of the probe, and the relative impedances present on the PCB, there may be some discrepancies between the measured signal and the probed signal. In order for a user to make proper inferences based upon the measured signal, the user must know how and to what extent the probe affects the circuit between the probed signal and the measured signal.

The teachings contained herein, therefore, are directed to guided assistance of an oscilloscope user to both accurately characterize a probe that is attached to the oscilloscope and to provide an intuitive display of how the probe affects a probed signal when the probe is configured. The present teachings suggest a representation of a probe configuration process that is straightforward and prioritized for the user. Different probe configuration categories are represented in respective probe configuration partitions, which are displayed to a user only when the relevant characteristics affect the probed signal. A user defines a probe in a sequence starting with the measurement channel 103 at the oscilloscope 102 and proceeding to a probe tip. A user then contemplates the measurement from the probe tip (i.e. the probed signal) to the measurement channel 103 of the oscilloscope 102. A specific embodiment of a graphical user interface according to the present teachings is developed in a Microsoft Windows operating system environment using Visual C++ and following conventional Microsoft Windows operating systems user interface standards.

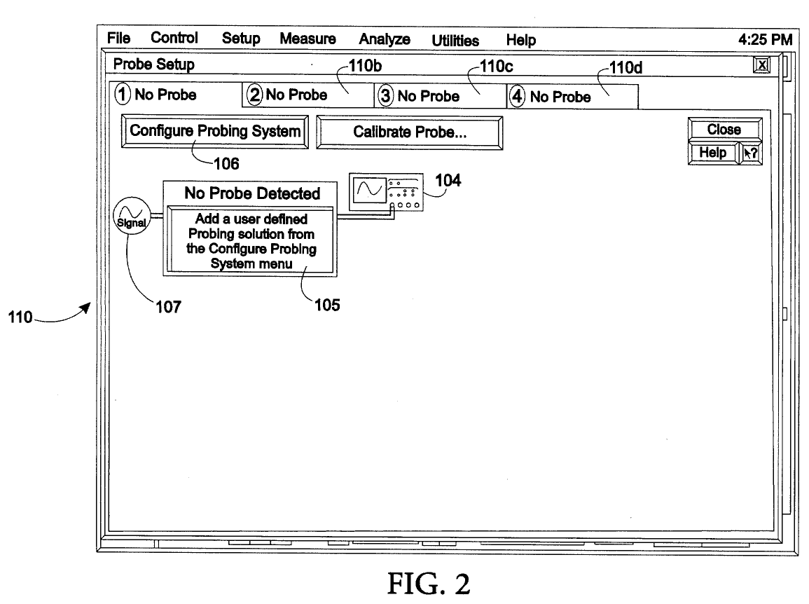

With specific reference to FIG. 2 of the drawings, there is shown an oscilloscope display with a Microsoft Windows operating system based probe configuration menu 110. In an oscilloscope 102 with four measurement channels 103, each measurement channel 103 has a separate probe configuration menu 110. When a first probe configuration menu 110a is shown on a display 111, second probe configuration menu 110b, third probe configuration menu 110c, and fourth probe configuration menu 110d are represented as tabs. Each probe configuration menu 110 is separate, but is similar in operation. Accordingly, only a single probe configuration menu 110 is disclosed herein, it being understood that the other probe configuration menu embodiments 110 are identical in operation to the specific embodiment disclosed herein.

The probe configuration menu 110 evokes the idea of a probed signal by showing a signal icon 107 on the display. The probe configuration menu 110 also evokes the idea of a measurement channel 103 on the oscilloscope 102 with a measurement channel icon 104. When displaying a preliminary probe configuration menu 110, a probe configuration partition 105 is shown between the signal icon 103 and the measurement channel icon 104. As shown in FIG. 2 of the drawings, a display of an electrical connection is shown to a specific measurement channel corresponding to the respective probe configuration menu 110. It is known that an oscilloscope is able to detect whether a probe 101 with known characteristics is attached. If a known probe is connected to the measurement channel, an initial probe configuration partition 105 is shown with a default probe configuration. If a probe is not attached to the measurement channel 103, the probe configuration partition 105 reflects the fact that no probe is detected and suggests adding a user defined probe using a configure probing system menu 106.

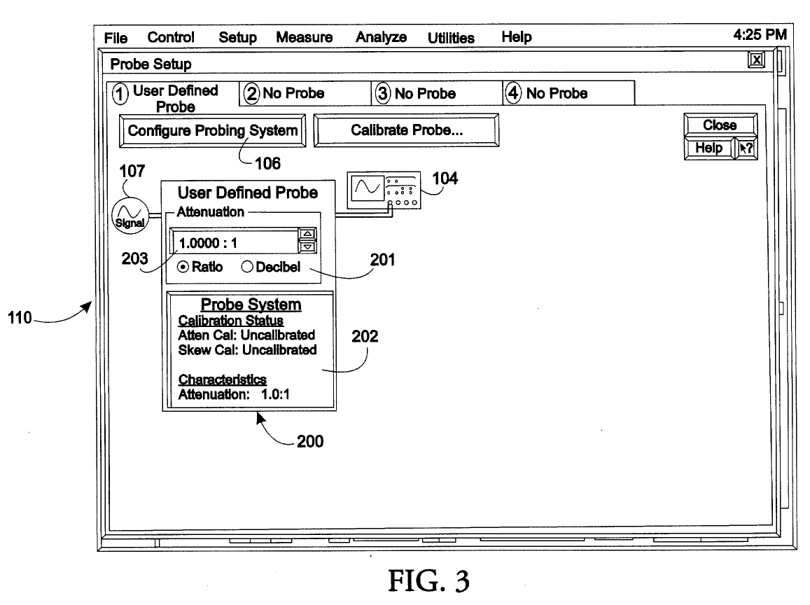

The configure probing system menu 106 permits selection of an option that provides a configure probing system partition 200. With specific reference to FIG. 3 of the drawings, the configure probing system partition 200 includes a user definition entry area 201 and an informational area 202. The user definition entry area 201 permits entry of an attenuation ratio 203, a default being 1:1, and whether the attenuation units are represented as a ratio or in decibels. The attenuation factor and units are arguably the most basic of probe definition elements and are the first options presented to a user. The informational area 202 includes information as to the calibration status of the attenuation and timing systems and also indicates the current attenuation characteristic.

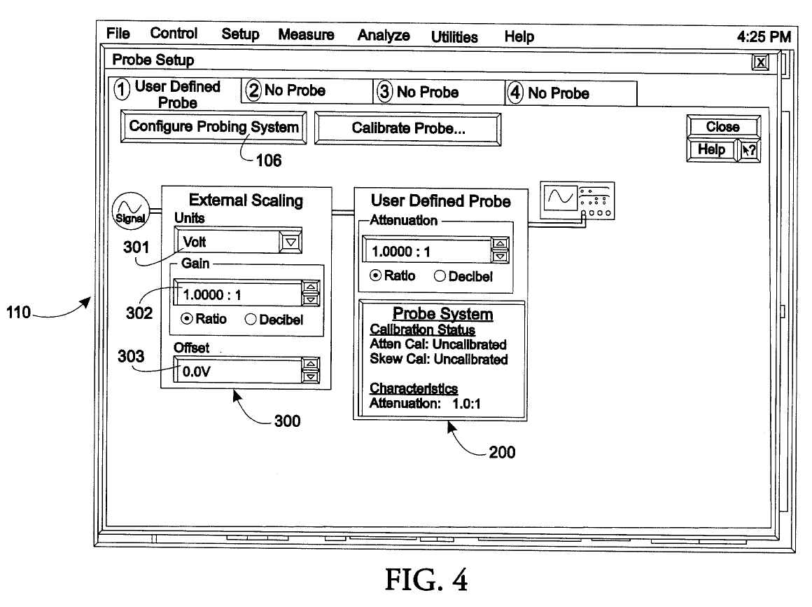

If a user wishes to include external scaling, the configure probing system menu 106 gives an option of adding it. With specific reference to FIG. 4 of the drawings, there is shown the probe configuration menu 110 with the external scaling option selected. Upon its selection, the external scaling system 300 is displayed as a separate probe configuration partition. The external scaling system 300 permits a user to specify units 301, gain 302 and the units of gain, and an offset 303. Upon viewing of the cascaded probe configuration partitions, a user is able to intuitively understand the circuit that is placed between the probed signal and the measurement channel 103.

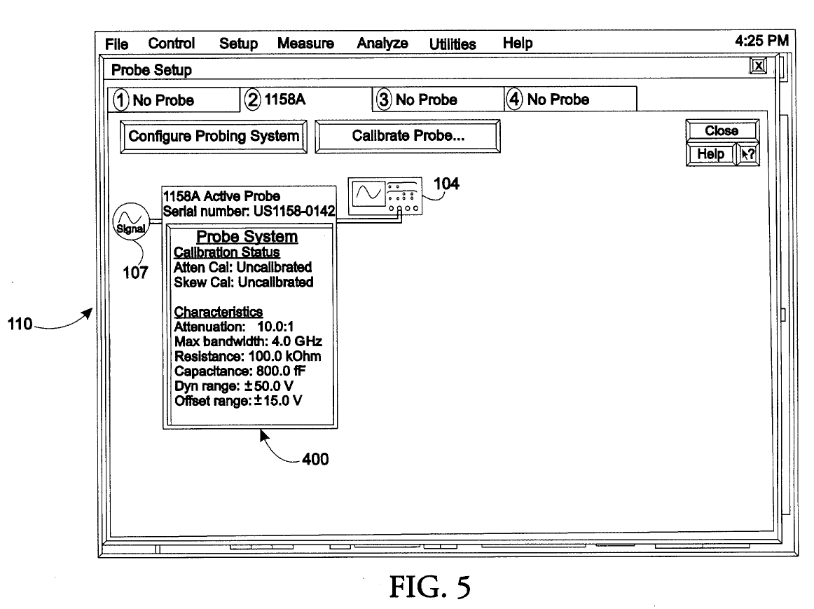

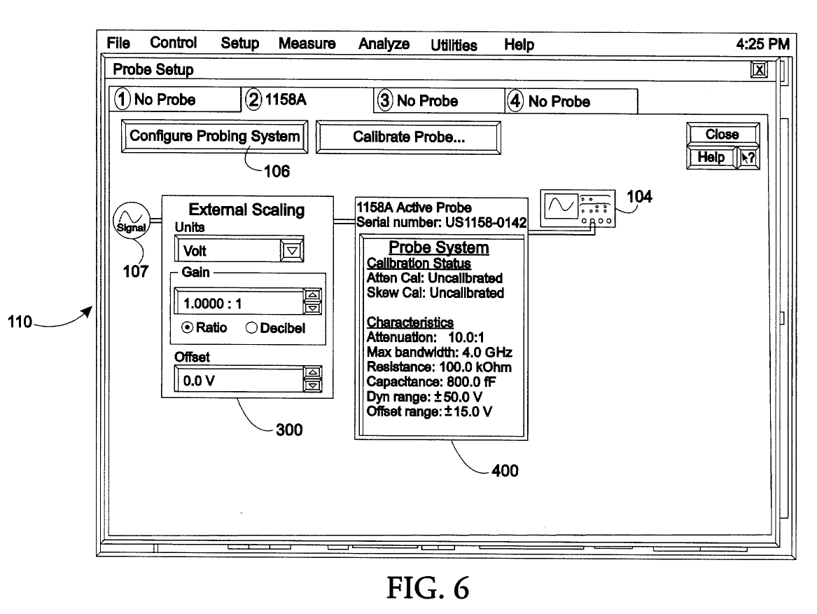

With specific reference to FIG. 5 of the drawings, there is shown a probe configuration menu 110 where the probe 101 that is attached to the measurement channel 103 is recognized by the oscilloscope 102. As a result of the recognition, a default probe configuration partition 400 is presented between the signal icon 103 and the measurement icon 104. The probe definition partition 400 in this case, reflects the characteristics of the detected probe and does not permit alterations be made to the probe characteristics. Characteristics displayed for a 1158A Active Probe are attenuation, maximum bandwidth, resistance, capacitance, dynamic range and offset range as well as the horizontal and vertical calibration status. With specific reference to FIG. 6 of the drawings, there is shown a second probe configuration partition comprising the external scaling probe configuration partition 300, which may be optionally added to the detected probe characteristics. As one of ordinary skill in the art appreciates, the first and second probe configuration partitions 300 and 400 shown in sequential display, provide a user with an intuitive picture of the electrical circuit that is placed between the probed signal and the measurement channel 103.

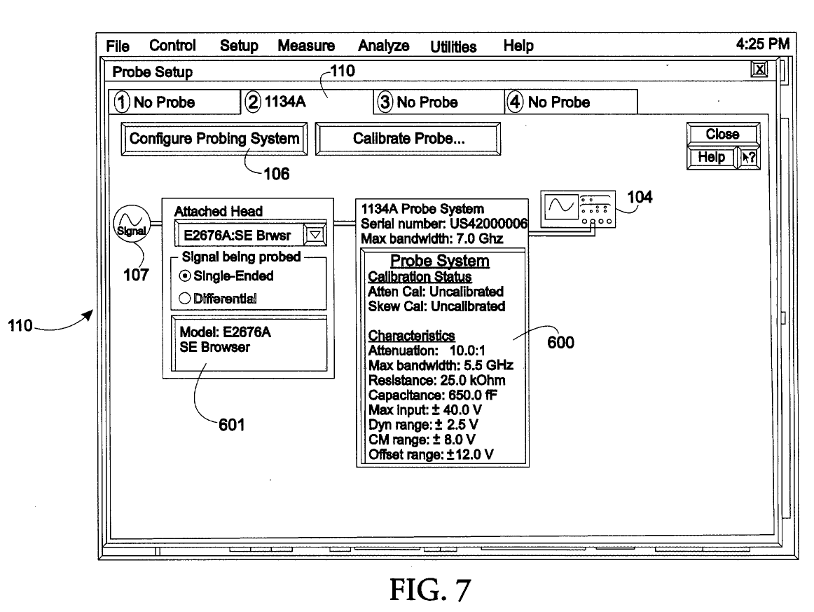

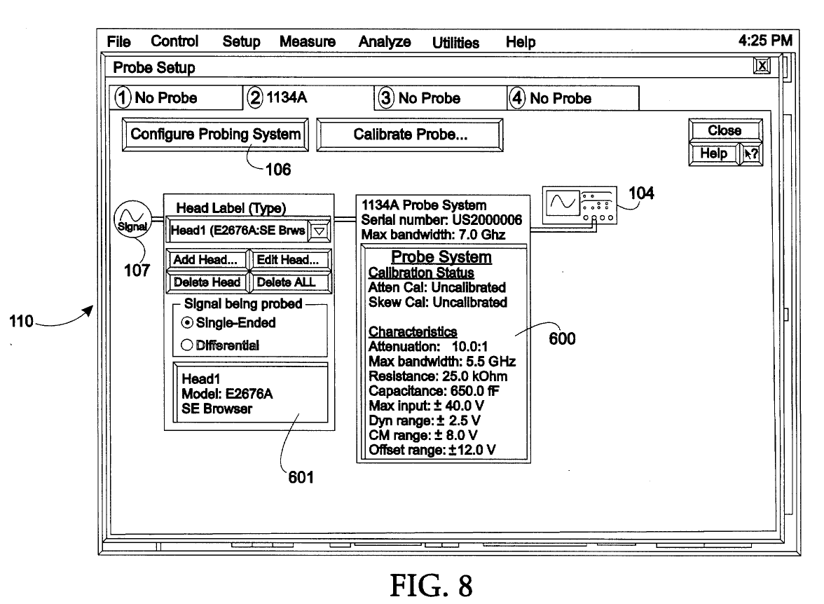

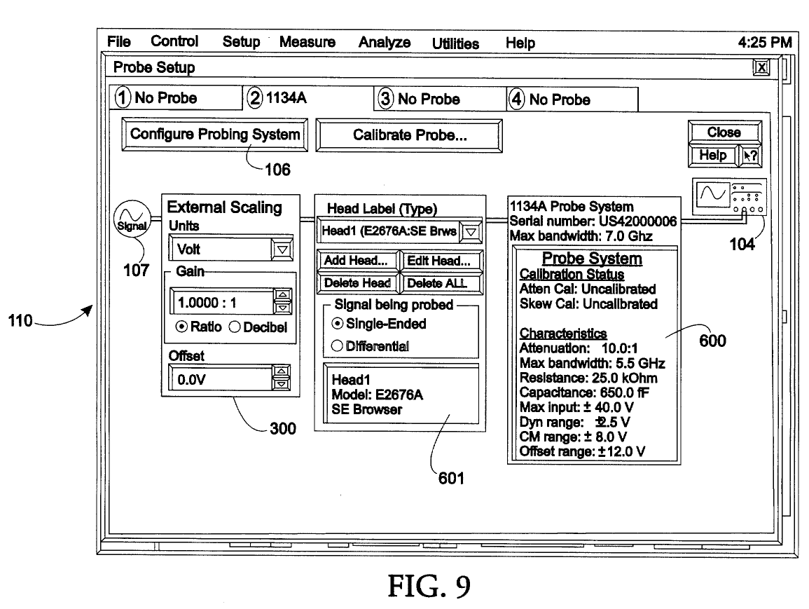

With specific reference to FIG. 7 of the drawings, there is shown another embodiment of the probe configuration menu 110. The probe configuration menu shown is for a relatively complex probe comprising a probe system and a plurality of available probe heads (not shown). Because there are a plurality of available probe heads, the contribution to the circuit based upon the probe heads is represented in a second probe configuration partition 601 while the contribution to the circuit based upon the probe is represented in a first probe configuration partition 600. The first and second probe configuration partitions are similar in format to the ones shown in FIGS. 5 and 6 of the drawings. The probe head configuration partition 601 presents a plurality of probe head options to a user using a conventional drop down menu and in the specific example indicates whether the probe head is a single-ended or differential probing system. With specific reference to FIG. 8 of the drawings, the probe head configuration partition 601 also permits a user to define a probe head for attachment to the detected probe. In the illustrated embodiment, the user may define a probe head name and whether the probe head is a singe-ended or differential probe. With specific reference to FIG. 9 of the drawings, there is shown the probe configuration menu of FIG. 8, but with the optional external scaling probe configuration partition 300 added as a third probe configuration partition.

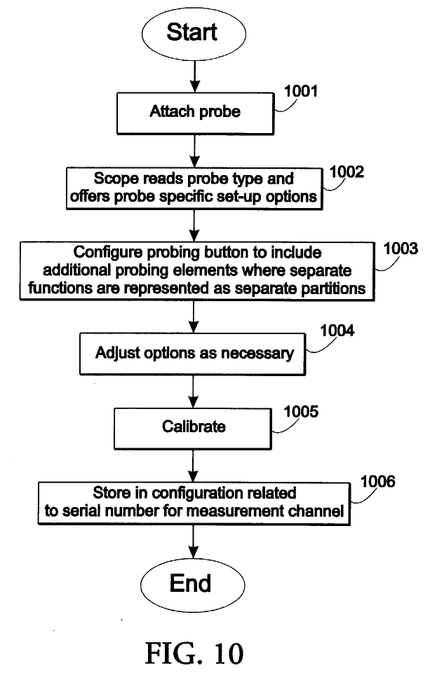

With specific reference to FIG. 10 of the drawings, there is shown a flow chart of a method for using a guided probe configuration according to the present teachings. In the method, the probe is connected to one of the measurement channels 1001. The oscilloscope senses that something is connected and makes a query. If the probe responds to the oscilloscope query with enough information to determine the type of probe that is connected, the oscilloscope presents a first probe configuration partition that corresponds to a default partition with probe specific configuration characteristics and configuration options. A user may maintain the default configuration or further modify 1004 the probe configuration partition and/or add second or third probe configuration partitions. Each separate probe function or probe is presented as a second probe configuration partition for ease of understanding and intuitive presentation of the probing circuit. When the probe is fully characterized, it may be calibrated 1004 upon user initiation. The calibration constants may be stored 1006 in a calibration file together with a probe serial number and measurement channel and used to correct the measured signal according to convention. If a different probe is connected or if the same probe is connected to a different measurement channel, the probe must be recalibrated.

The software that implements the disclosed user interface is programmed using a Microsoft Visual Studio development environment using Microsoft Visual C++ software. The software defines a base probe class with multiple extensions, a different extension for each different probe category. The software also defines a base adapter class with extensions for each type of probe accessory, which may or may not be used in conjunction with the probe. A class defines the electrical and functional characteristics for the probe or probe accessory category. In a specific embodiment, there are three different types of probe categories, a standard probe category, a unique probe category and a smart probe category. Accordingly, there are three different defined extensions of the base probe class, a standard probe class, a unique probe class, and a smart probe class. In addition there are class extensions for a probe adapter and a probe head based upon the base probe adapter class. In other embodiments, one of ordinary skill in the art may define and implement additional classes and class extensions for a new categories of probes and adapters and still operate within the constructs of the present teachings. Each class is established according to a user model for how the probe or accessory defined for each class is used.

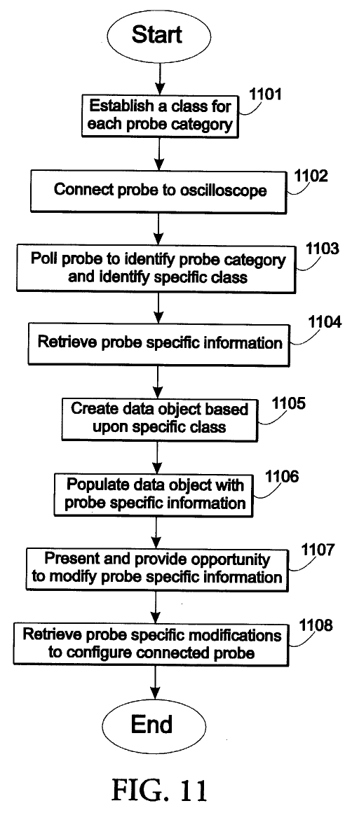

With specific reference to FIG. 11 of the drawings, there is shown a general process for identification and initial configuration of a probe upon connection of a probe to the oscilloscope. As one of ordinary skill in the art appreciates, an appropriate data object is generated for the probe that is connected to each oscilloscope measurement channel. The oscilloscope software establishes 1101 at least one class for each probe category. Upon connection 1102 of a specific probe to the oscilloscope, the oscilloscope senses the connection and polls 1103 the probe to retrieve a resistive value that indicates a specific probe category, and therefore a specific class, that is associated with the connected probe. If the probe category is a smart probe, the oscilloscope polls the probe further to identify a model no. and serial no. Based upon the model no. in the case of a smart probe or upon the resistive value in the case of a standard or unique probe, the oscilloscope retrieves probe specific information from a configuration file associated with the probe. The oscilloscope creates 1105 a data object based upon the specific class and populates 1106 the data object with the probe specific information. As discussed herein, the oscilloscope provides the user with an opportunity to examine and perhaps modify 1107 the probe configuration options. Only those options that are available for the connected probe are presented to the user rendering the user interface simpler and more intuitive even for the more complicated probes and probe accessories. When the user has completed any modifications to probe specific information, the oscilloscope retrieves the information from the probe configuration partitions and configures 1108 the probe accordingly.

As an example, a standard probe is the simplest construct. As is conventional in the industry, a resistive value located on the standard probe is polled by an oscilloscope to identify an attenuation factor and an oscilloscope input impedance setting for the standard probe that is connected to the oscilloscope. The functional characteristics of a standard probe are typically minimally complex and may not be altered. Accordingly, the probe configuration partition that is associated with the standard probe (not shown as an example in the drawings) is presented on the oscilloscope display primarily for informational purposes. When the oscilloscope determines that the connected probe is a standard probe and also determines a specific attenuation factor for the probe, the oscilloscope software generates a data object based upon the standard probe class and populates the data object with appropriate data based upon the specific characteristics of the probe, such as attenuation factor.

In another example, a unique probe category represents a probe that is more complex than the standard probe category such as an active probe or a probe having internal controls for attenuation or gain factor. A unique probe does not have the EEPROM, that stores the probe characteristics on the probe, like the smart probe, When the oscilloscope polls one of the unique probes it is identified as a unique probe through the resistive reading. The oscilloscope software generates a data object based upon the unique probe class and retrieves information from a configuration file that is associated with resistive value of the unique probe. The information from the configuration file is used to populate the data object with default probe set-up information for the unique probe that is connected to the oscilloscope as well as the range of options for the probe that may be selected by the user. The associated probe configuration partition is displayed to the user for informational purposes as well as for purposes of modifying the probe configuration as appropriate.

In another example, a smart probe type represents the most complex type of probe that is known at the time of the present teachings. When a smart probe is connected to the oscilloscope, the result of the oscilloscope poll of the resistive element identifies the connected probe as a smart probe and creates a data object based upon the smart probe class. The oscilloscope then accesses the smart probe through an I2C communications bus and retrieves information from a memory chip on the smart probe. The memory chip stores information such as model no., serial no., as well as the basic electrical characteristics of the probe. Based upon the model no., the software accesses the related configuration file to retrieve data for populating the smart probe data object. The data object is populated with default set-up data for the smart probe as well as other available options, such as adapters and probe heads. The smart probe configuration file contains the types of probe heads and adapters that are available to work in conjunction with the model no. of the smart probe that is connected to the oscilloscope. Advantageously, this permits presentation of only those options that are available to the user with the smart probe that is connected.

As mentioned herein, the probe heads also have a class associated therewith. Because some probes work in conjunction with probe heads, the base probe class also has a construct for storage of up to 10 possible probe head pointers. The probe head pointer is an address to one of a possible 10 probe head data objects. When the user configures a particular probe head 1105, a next probe head pointer is stored in the smart probe data object and points to the configured probe head data object. In this way, the probe data object is logically linked to the configured probe head data objects that are associated with the smart probe data object. The contents of the various data objects inform the oscilloscope software for presentation of only the currently applicable data in the probe configuration partitions.

Frequent updates to embedded software present a challenge to hardware manufacturers. Software updates undergo a quality control and testing process to assure proper functionality prior to shipment of updated hardware. The quality control and testing process can be time consuming and expensive. A method according to the present teachings provides a modularity that advantageously permits new probes, adapters and probe heads to be added by the manufacturer of the oscilloscope with minimal quality assurance testing requirements. The update comprises only a modification of configuration files that are associated with the new or updated probe, probe head, or accessory.

These and other embodiments have been described by way of example and are illustrative only. Other embodiments will occur to one of ordinary skill in the art with benefit of the present teachings. For example, many different types of probes may be defined using first, second and third probe configuration partitions and perhaps fourth and fifth probe configuration partitions as desired and appropriate. The probe characteristics may be presented differently than what is illustrated. Accordingly, the scope of the present teachings is defined only in the appended claims.

1. A method of establishing a probe configuration comprising the steps of:
displaying a signal icon and a measurement channel icon,
displaying a probe configuration partition interposed between said input icon and said measurement icon that reflects the electrical characteristics of a circuit interposed between a probed signal and a measurement channel,
accepting changes to said probe configuration partition to generate said probe configuration, and
using said probe configuration to adapt a probed signal for presentation to a user.

2. A method as recited in claim 1 wherein said signal icon is a graphic representation of an electrical signal.

3. A method as recited in claim 1 wherein said measurement channel icon is a graphic representation of an oscilloscope.

4. A method as recited in claim 1 and further comprising the steps of presenting said signal icon on a left-hand side of the display, said measurement channel icon on a right-hand side of the display, and said probe configuration partition therebetween.

5. A method as recited in claim 1 wherein first and second probe configuration partitions are interposed between said signal icon and said measurement icon.

6. A method as recited in claim 5 wherein said first probe configuration partition shows at least one probe characteristic selected from the group consisting of gain, attenuation, attenuation calibration, attenuation skew, bandwidth, resistance, capacitance, offset range, dynamic range, and common mode range.

7. A method as recited in claim 6 wherein said second probe configuration partition shows at least one characteristic of auxiliary probe components.

8. A method as recited in claim 7 and further comprising a third probe configuration partition, wherein said third probe configuration partition shows external scaling characteristics.

9. A method as recited in claim 5 wherein said probe configuration partitions are displayed upon user initiation.

10. A method as recited in claim 1 and further comprising the step of:
detecting a type of probe and presenting a simplified default probe configuration partition.

11. An apparatus for establishing a probe configuration and measuring an electrical signal comprises:
a display showing a signal icon, a measurement icon, and a probe configuration partition disposed between said input icon and said measurement icon that reflects the electrical characteristics of a probe,
means for accepting changes to said probe configuration partition to generate said probe configuration,
means for measuring said signal with said probe to obtain a measured signal, and
means for adapting said measured signal according to said probe configuration for presentation of said signal to a user.

12. An apparatus as recited in claim 11 wherein said signal icon is displayed on a left-hand side of the display, said measurement icon is displayed on a right-hand side of the display, and said probe configuration partition is displayed therebetween.

13. An apparatus as recited in claim 11 and wherein said probe configuration partition comprises first and second probe configuration partitions.

14. An apparatus as recited in claim 11 wherein said first probe configuration partition shows one or more probe characteristics selected from the group consisting of gain, attenuation, attenuation calibration, attenuation skew, bandwidth, resistance, capacitance, offset range, dynamic range, and common mode range.

15. An apparatus as recited in claim 14 wherein said second probe configuration partition shows characteristics of auxiliary probe components.

16. An apparatus as recited in claim 15 and further comprising a third probe configuration partition, wherein said third probe configuration partition shows external scaling probe characteristics.

17. An apparatus as recited in claim 13 wherein said probe configuration partitions are displayed upon user initiation.

18. An apparatus as recited in claim 11 and further comprising a means for detecting a type of probe connected to said means for measuring for presentation of a simplified default probe configuration partition.

19. A method for configuring an oscilloscope probe comprising the steps of:
establishing at least one class, each class defining a probe category,
connecting said probe to an oscilloscope,
polling said probe to retrieve a probe category associated with said probe and said probe identification,
retrieving probe specific data based upon said probe identification that defines a specific class from said at least one class,
creating an object based upon said specific class, populating said object with said probe specific data,
providing an opportunity to modify said probe specific data through a user interface,
using said modified probe specific data to configure said probe.
